(19) United States
(12) Patent Application Publication
(10) Pub. No.: US 2009/0057731 A1
(43) Pub. Date: Mar. 5, 2009

(54) SEMICONDUCTOR DEVICE AND METHOD OF MANUFACTURING THE SAME

(76) Inventor: Yuichiro KITAJIMA, Chiba-shi (JP)

Correspondence Address: BRINKS HOFER GILSON & LIONE, P.O. BOX 10395, CHICAGO, IL, 60610, US

(21) Appl. No.: 12/200,122

(22) Filed: Aug. 28, 2008

(30) Foreign Application Priority Data
Aug. 29, 2007 (JP) JP2007-222659

(51) Int. Cl. H01L 29/78

(52) U.S. Cl. 257/288; 257/E29.255

(57) ABSTRACT

In a MOS transistor, a structure of trenches or fins arranged in parallel to a gate length direction is formed in a stepwise manner along a gate width direction to thereby reduce a step height of each step. Even if the MOS transistor includes a deep trench or a high fin in order to increase driving performance per unit area, a uniform impurity concentration in a channel region, a source diffusion layer, and a drain diffusion layer can be made by an ion implantation method. Accordingly, there can be obtained a stable characteristic that variation in the characteristic due to a surface on which the channel is formed does not appear, and a lateral MOS transistor with high driving performance having a reduced on-resistance per unit area can be provided.

### RELATED APPLICATIONS

This application claims priority under 35 U.S.C. §119 to Japanese Patent Application No. JP2007-222659 filed on Aug. 29, 2007, the entire content of which is hereby incorporated by reference.

### BACKGROUND OF THE INVENTION

1. Field of the Invention

The present invention relates to a semiconductor device including a metal oxide semiconductor (MOS) transistor with high driving performance.

2. Description of the Related Art

A MOS transistor with low on-resistance is needed in an application which requires higher efficiency and higher output current for an integrated circuit (IC) such as voltage regulator (hereinafter, referred to as VR) or switching regulator (hereinafter, referred to as SWR) for controlling a power supply voltage to output a constant voltage. In this case, use of an external power MOS transistor can meet the need for a MOS transistor with high driving performance. However, the number of components increases as the entire power supply control circuit, and hence there is a fear for increase in cost due to the increase in the number of components and in the assembly thereof.

Incorporation of the external power MOS transistor into the VR or SWR can be a method for reducing the cost. The incorporation allows one-chip integration, whereby the excess cost caused by the increased number of components and the assembly thereof can be reduced. While a vertical MOS structure in which current flows in a depth direction of a substrate is a mainstream structure in the power MOS transistor, and shows remarkably excellent performance as a single element, it is difficult to incorporate the power MOS transistor having the vertical MOS structure into the VR or SWR. Accordingly, in a case where a lateral MOS structure is employed when the power MOS transistor is incorporated into the VR or SWR, a transistor size needs to be made larger in order to be a low on-resistance, and hence there is a fear for increase in a chip size.

A method of increasing a channel width of a transistor by forming a trench in a channel portion can be a countermeasure (for example, refer to FIG. 2 of JP 3405681 B). According to this method, the channel width can be made larger based on the depth of the trench while the element area is kept constant, whereby the resistance in the channel portion of the element can be made smaller, that is, the resistance of the element itself can be made smaller to thereby reduce the on-resistance. Further, formation of a plurality of trenches can enlarge the channel width based on installation density of those trenches, permitting more effective reduction of the on-resistance.

Moreover, there is a structure in which a waveform shape such as a rectangular waveform shape or a triangular waveform shape is formed along a channel width direction by alternately arranging recesses and protrusions extending in a channel length direction and in which driving performance is increased without expansion of the transistor region (for example, refer to JP 05-75121 A).

In the structure of the invention described in JP 3405681 B, production tolerance causes not only variation in a concentration of a well diffusion layer but also variation in a junction depth of the well diffusion layer, resulting in variation in the length of the channel which is formed in the side surface of the trench, whereby element characteristics are liable to vary in the structure. Further, the channel formed in the side surface of the trench has a structure in which a channel length varies in accordance with a diffusion depth of the well, which limits a device design in a case where a MOS transistor is incorporated into the VR or SWR.

Further, a distance from a channel end of a semiconductor substrate surface to a heavily-doped drain diffusion layer and a distance from a channel end of the side surface of the trench to the heavily-doped drain diffusion layer are different, and the distance from the channel end of the side surface of the trench to the heavily-doped drain diffusion layer is longer. Then, resistance component thereof becomes larger and the amount of current in a bottom portion of the trench is reduced. Therefore, this structure does not highly exert effects of the trench for expanding a channel width per unit area.

In the invention described in JP 05-75121 A, driving performance per unit area can be improved by deepening a step in the rectangular waveform shape. As shown in FIG. 9, in a case where the trench formed in a semiconductor substrate 102 has one step, a trench width v and a trench interval 1 are made smaller and a trench depth w is made smaller in order to increase a gate width per unit area, whereby the driving performance per unit area can be improved. However, a step height between a surface of the semiconductor substrate 102 and the bottom portion of the trench tends to be increased. Moreover, when impurities are implanted to the channel region by an ion implantation method at the time of adjusting the threshold voltage of the MOS transistor, the large step height prevents uniform ion implantation to the surface of the semiconductor substrate 102, the bottom portion of the trench, and the side surface of the trench, avoiding the formation of the channel region having a uniform impurity concentration. Accordingly, the trench width v, the trench interval 1, and the trench depth w are restricted, to thereby provide a structure in which further improvement of the driving performance per unit area cannot be made.

### SUMMARY OF THE INVENTION

In order to solve the above problems, the present invention employs the following means:

(1) A semiconductor device including a structure in which a MOS transistor includes trenches arranged in a channel region in parallel to a gate length direction, in which the structure is formed into a stepwise structure in a gate width direction;

(2) A semiconductor device in which the stepwise structure protrudes downward from a surface of a semiconductor substrate;

(3) A semiconductor device in which the stepwise structure protrudes upward from a surface of a semiconductor substrate;

(4) A semiconductor device in which the stepwise structure includes at least two steps in the channel region; and

(5) A semiconductor device in which the MOS transistor includes a source diffusion layer and a drain diffusion layer, which are also formed into the stepwise structure.

Since trenches or fins which are arranged in parallel to the gate length direction are configured to be a stepwise form in a gate width direction, to thereby reduce the step height of each step formed between the surface of the semiconductor substrate and either a bottom portion of the trench or a top portion of the fin, the MOS transistor can be configured to have uniform impurity concentration in the channel region, the source diffusion layer, and the drain diffusion layer by an ion implantation method even if the MOS transistor includes a deep trench or a high fin in order to increase driving performance per unit area. With this structure, there can be obtained a stable characteristic that variation in the characteristic due to a surface on which the channel is formed does not appear, and a lateral MOS transistor with high driving performance having a reduced on-resistance per unit area can be provided.

### BRIEF DESCRIPTION OF THE DRAWINGS

In the accompanying drawings:

FIG. 1 is a perspective view showing a semiconductor device according to a first embodiment of the present invention;

FIG. 2 is a perspective view showing a cross section taken along the line A-A′ of FIG. 1;

FIG. 3 is a top view showing the semiconductor device according to the first embodiment of the present invention;

FIG. 4 is a sectional view taken along the line C-C′ of FIG. 3;

FIG. 5 is a perspective view showing a semiconductor device according to a second embodiment of the present invention;

FIG. 6 is a perspective view showing a cross section taken along the line D-D′ of FIG. 5;

FIG. 7 is a top view showing the semiconductor device according to the second embodiment of the present invention;

FIG. 8 is a sectional view taken along the line F-F′ of FIG. 7; and

FIG. 9 is a sectional view showing a semiconductor device according to a conventional embodiment.

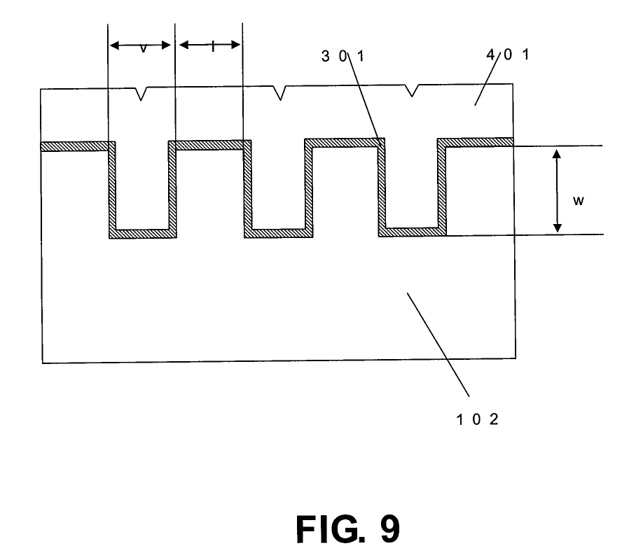

### DETAILED DESCRIPTION OF THE PREFERRED EMBODIMENTS

Hereinafter, preferred embodiments according to the present invention are described in detail with reference to the drawings.

### First Embodiment

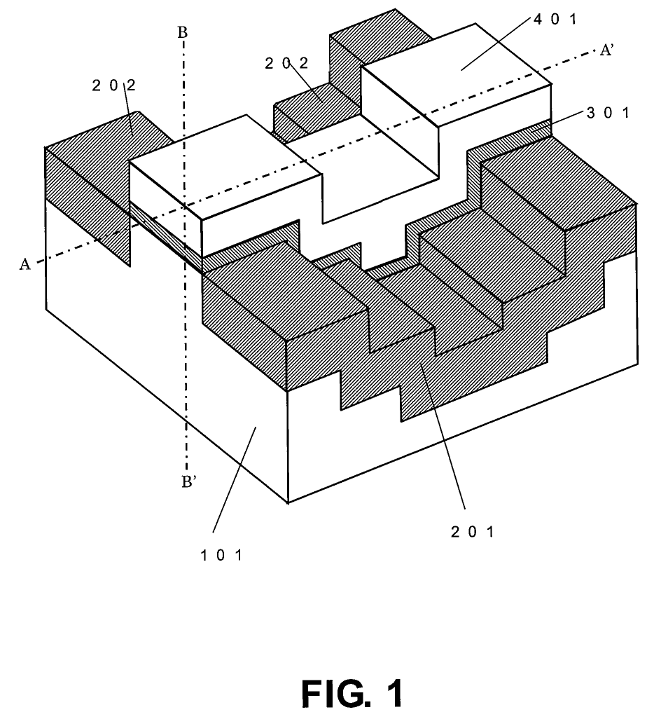

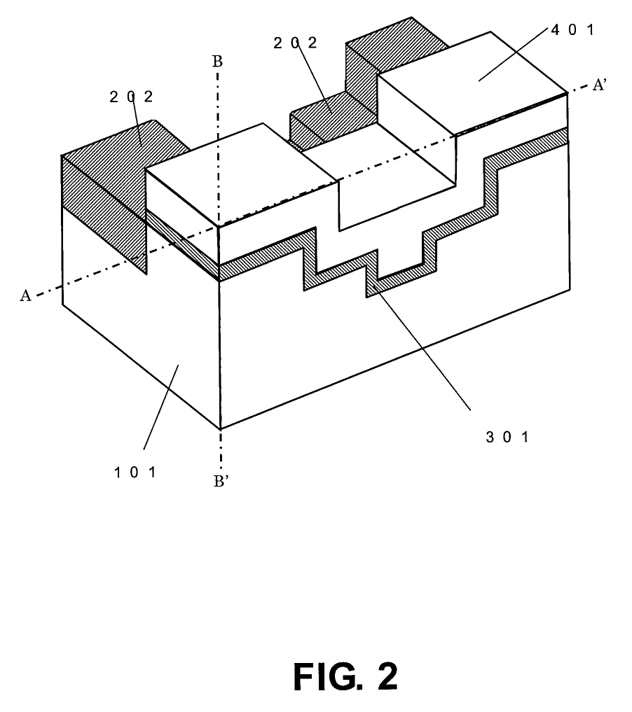

FIGS. 1 to 4 show a semiconductor device according to a first embodiment of the present invention. FIG. 1 shows a structure of a lateral trench MOS transistor according to the first embodiment of the present invention. FIG. 2 shows a sectional view of a plane including the chain line A-A′ and the chain line B-B′ of FIG. 1.

As shown in FIG. 1, an n-type drain diffusion layer 201 and an n-type source diffusion layer 202 which become heavily-doped impurity layers are formed on a p-type semiconductor substrate 101, a gate insulating film 301 is formed on the p-type semiconductor substrate 101, and further a gate electrode 401 is formed on the gate insulating film 301. In other words, the p-type semiconductor substrate 101, the n-type drain diffusion layer 201, the n-type source diffusion layer 202, and the gate electrode 401 serve as a substrate, a drain, a source, and a gate of a MOS transistor, respectively, to thereby form a MOS transistor.

The n-type drain diffusion layer 201 and the n-type source diffusion layer 202 are formed with trenches each protrude downward so as to form a groove in a deep direction from a surface of the p-type semiconductor substrate 101. The trenches are formed so as to be made deeper in a direction from A to A′ of the chain line A-A′ in a stepwise manner, and then, to be made shallower in a stepwise manner.

Further, as shown in FIG. 2, the p-type semiconductor substrate 101 provided under the gate insulating film 301 is also formed with trenches each protrude downward from the surface of the semiconductor substrate 101 so as to form a groove in the deep direction from the substrate surface of the p-type semiconductor substrate 101, similarly to the n-type drain diffusion layer 201 and the n-type source diffusion layer 202. The trenches are formed so as to be made deeper in a direction from A to A′ of the chain line A-A′ in a stepwise manner, and then, to be made shallower in a stepwise manner. The trenches formed so as to be deeper and shallower in a stepwise manner construct a continuous belt-like trench in which the trenches are arranged in parallel to a gate length direction from the n-type drain diffusion layer 201 to the n-type source diffusion layer 202 through the p-type semiconductor substrate 101 provided under the gate insulating film 301.

The gate insulating film 301 is formed so as to have a uniform film thickness in conformity with the configuration of the p-type semiconductor substrate 101 provided immediately below the gate insulating film 301. The gate electrode 401 is formed on the gate insulating film 301 so as to cover the gate insulating film 301.

Operations of the lateral MOS transistor are described. In a state where a positive voltage is applied to the n-type drain diffusion layer 201 and a voltage lower than the voltage applied to the n-type drain diffusion layer 201, that is, a negative voltage, is applied to the n-type source diffusion layer 202, when the positive voltage is applied to the gate electrode 401, the surface of the p-type semiconductor substrate 101 provided immediately below the gate insulating film 301 is inverted into n-type. As a result, electrons pass from the n-type source diffusion layer 202 through the surface of the p-type semiconductor substrate 101 which has been inverted into n-type to flow into the n-type drain diffusion layer 201.

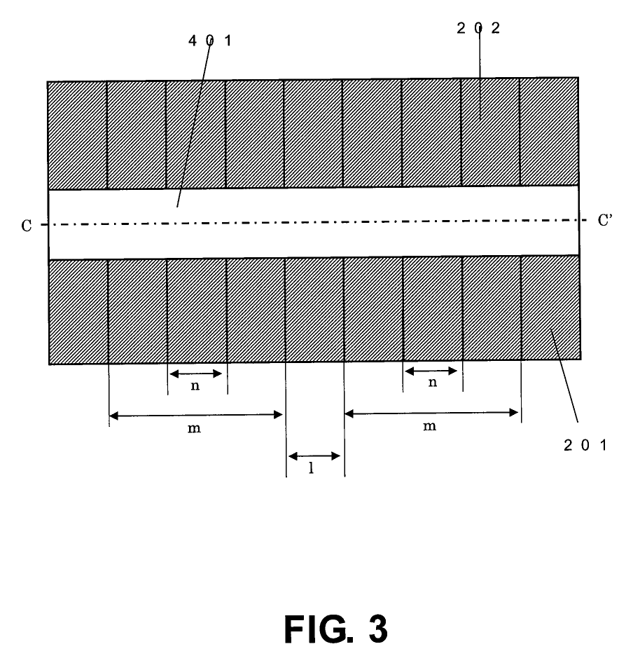

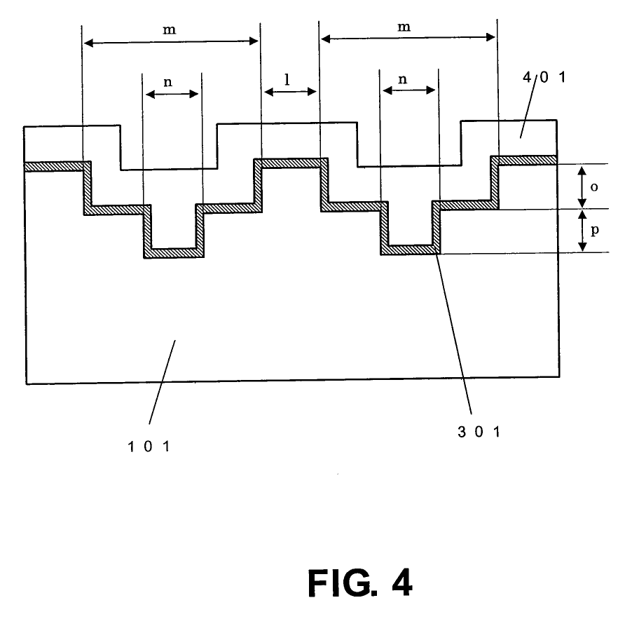

FIG. 3 is a top view showing the lateral MOS transistor according to the first embodiment of the present invention. FIG. 4 is a sectional view taken along the chain line C-C′ of FIG. 3. FIG. 3 shows that the n-type drain diffusion layer 201 and the n-type source diffusion layer 202 are formed via the gate electrode 401 and have belt-like trenches which are arranged in parallel to the gate length direction. As shown in FIG. 4, belt-like trenches are also formed in the p-type semiconductor substrate 101 provided immediately below the gate insulating film 301 to construct a continuous belt-like trench extending from the n-type source diffusion layer 202 to the n-type drain diffusion layer 201. Besides, the trenches are formed so as to be made deeper in a direction from C to C′ of the chain line C-C′ in a stepwise manner, and then, to be made shallower in a stepwise manner.

As shown in FIGS. 3 and 4, the continuous arrangement of the stepwise trenches increases a gate width of the MOS transistor. Therefore, an amount of current can be increased and an amount of current per unit area can be increased by making smaller the trench interval 1, a first trench width m, and a second trench width n, and making larger a first trench depth o and a second trench depth p. In the above example, the stepwise trenches are formed as two steps. In a case where the step height between the trenches is large, the number of steps of the stepwise trenches can be further increased to thereby reduce the step height.

In the above, a description has been made on the n-type channel MOS transistor in which the p-type semiconductor substrate is used as a substrate, and the n-type diffusion layers as a source and a drain, but this structure can be applied to a p-type channel MOS transistor. This structure can also be applied to a MOS transistor structure in which there is used a well having a substrate formed into a semiconductor substrate. Besides, this structure can also be applied to a MOS transistor including offset layers of low concentration, which are provided in the source diffusion layer and the drain diffusion layer.

In the MOS transistor according to the first embodiment of the present invention, the belt-like trenches arranged in parallel to the gate length direction are formed in a stepwise manner in the gate width direction to thereby reduce the step height between the surface of the semiconductor substrate and the bottom portion of the trench. As a result, even if the MOS transistor includes a deep trench in order to enhance the driving performance per unit area, the MOS transistor can make the impurity concentration uniform in the channel region, the source diffusion layer, and the drain diffusion layer by using the ion implantation method.

With these structures, when a MOS transistor with high driving performance is incorporated into a VR or SWR, even if a MOS transistor whose gate width per unit area is increased by the use of the trench is used, there can be obtained a stable characteristic that variation in the characteristic due to a surface on which the channel is formed does not appear, and a lateral MOS transistor with high driving performance having a reduced on-resistance per unit area can be provided.

### Second Embodiment

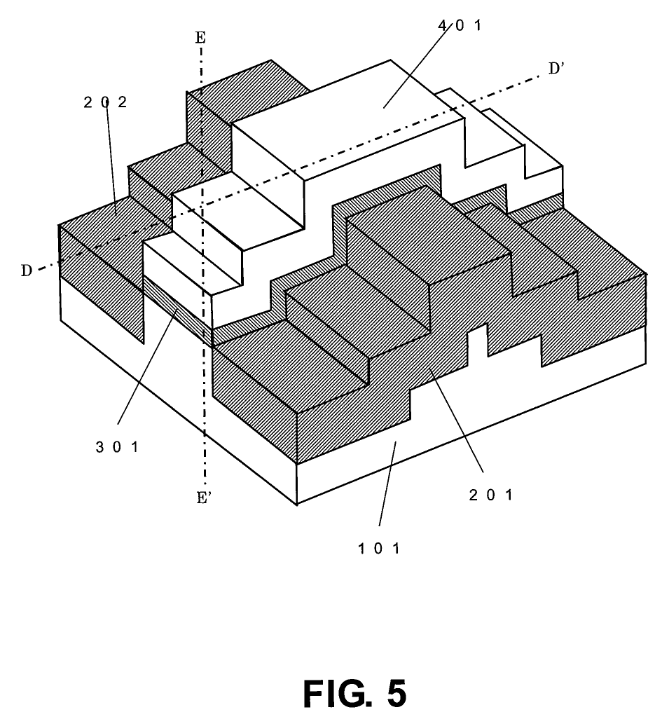

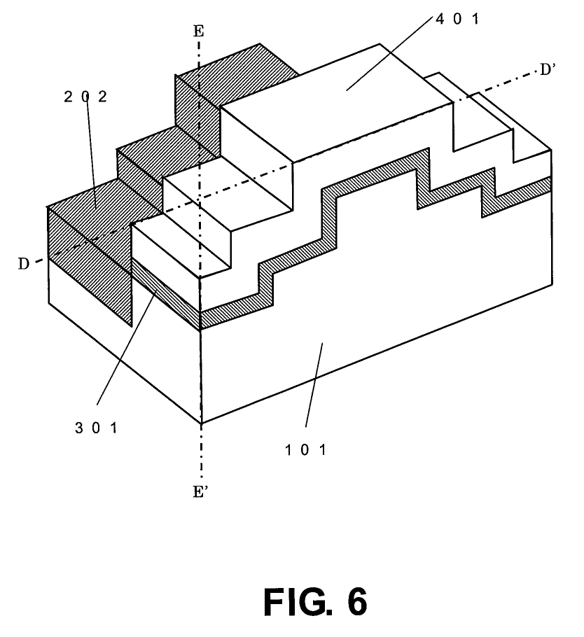

FIGS. 5 to 8 show a semiconductor device according to a second embodiment of the present invention. FIG. 5 shows a structure of a lateral MOS transistor according to the second embodiment of the present invention. FIG. 6 shows a sectional view of a plane including the chain line D-D′ and the chain line E-E′ of FIG. 5.

As shown in FIG. 5, an n-type drain diffusion layer 201 and an n-type source diffusion layer 202 which become heavily-doped impurity layers are formed on a p-type semiconductor substrate 101, a gate insulating film 301 is formed on the p-type semiconductor substrate 101, and further a gate electrode 401 is formed on the gate insulating film 301. The p-type semiconductor substrate 101, the n-type drain diffusion layer 201, the n-type source diffusion layer 202, and the gate electrode 401 serve as a substrate, a drain, a source, and a gate of a MOS transistor, respectively, to thereby form a MOS transistor.

The n-type drain diffusion layer 201 and the n-type source diffusion layer 202 are formed with fins each protrude upward so as to form a hump in a high direction from a surface of the p-type semiconductor substrate 101. The fins are formed so as to be made higher in a direction from D to D′ of the chain line D-D′ in a stepwise manner, and then, to be made lower in a stepwise manner.

Further, as shown in FIG. 6, the p-type semiconductor substrate 101 provided under the gate insulating film 301 is also formed with fins each protrude upward from the surface of the semiconductor substrate 101 so as to form a hump in a high direction from the substrate surface of the p-type semiconductor substrate 101, similarly to the n-type drain diffusion layer 201 and the n-type source diffusion layer 202. The fins are formed so as to be made higher in a direction from D to D′ of the chain line D-D′ in a stepwise manner, and then, to be made lower in a stepwise manner. The fins formed so as to be higher and lower in a stepwise manner construct a continuous belt-like fin in which the fins are arranged in parallel to a gate length direction from the n-type drain diffusion layer 201 to the n-type source diffusion layer 202 through the p-type semiconductor substrate 101 provided under the gate insulating film 301.

The gate insulating film 301 is formed so as to have a uniform film thickness in conformity with the configuration of the p-type semiconductor substrate 101 provided immediately below the gate insulating film 301. The gate electrode 401 is formed on the gate insulating film 301 so as to cover the gate insulating film 301.

Operations of the lateral MOS transistor are described. In a state where a positive voltage is applied to the n-type drain diffusion layer 201 and a voltage lower than the voltage applied to the n-type drain diffusion layer 201, that is, a negative voltage, is applied to the n-type source diffusion layer 202, when the positive voltage is applied to the gate electrode 401, the surface of the p-type semiconductor substrate 101 provided immediately below the gate insulating film 301 is inverted into n-type. As a result, electrons pass from the n-type source diffusion layer 202 through the surface of the p-type semiconductor substrate 101 which has been inverted into n-type to flow into the n-type drain diffusion layer 201.

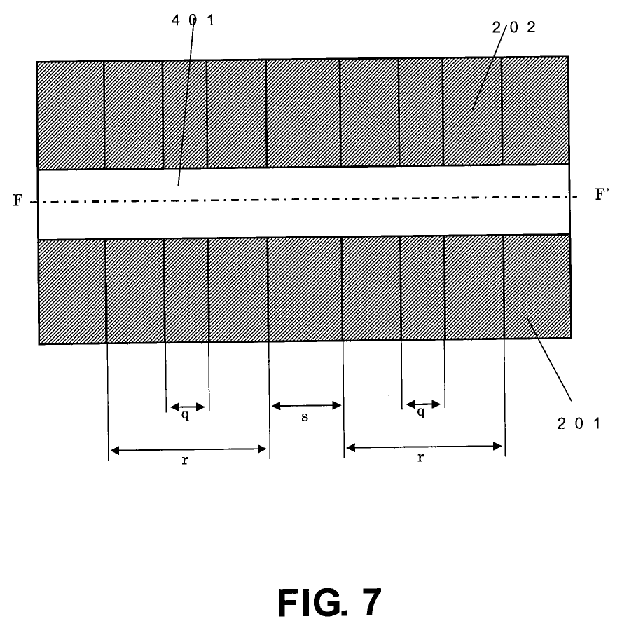

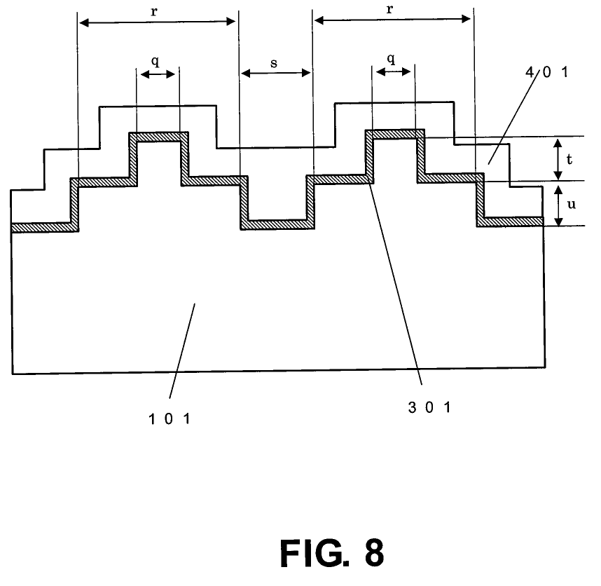

FIG. 7 is a top view showing the lateral MOS transistor according to the second embodiment of the present invention. FIG. 8 is a sectional view taken along the chain line F-F′ of FIG. 7. FIG. 7 shows that the n-type drain diffusion layer 201 and the n-type source diffusion layer 202 are formed via the gate electrode 401 and have belt-like fins which are arranged in parallel to the gate length direction. As shown in FIG. 8, belt-like fins are also formed in the p-type semiconductor substrate 101 provided immediately below the gate insulating film 301 to construct a continuous belt-like fin extending from the n-type source diffusion layer 202 to the n-type drain diffusion layer 201. Besides, the fins are formed so as to be made higher in a direction from F to F′ of the chain line F-F′ in a stepwise manner, and then, to be made lower in a stepwise manner.

As shown in FIGS. 7 and 8, the continuous arrangement of the stepwise fins increases a gate width of the MOS transistor. Therefore, an amount of current can be increased and an amount of current per unit area can be increased by making smaller a first fin width q, a second fin width r, and a fin interval s, and making larger a first fin height t and a second fin height u. In the above example, the stepwise fins are formed as two steps. In a case where the step height between the fins is large, the number of steps of the stepwise fins can be increased to thereby reduce the step height.

In the above, a description has been made on the n-type channel MOS transistor in which the p-type semiconductor substrate is used as a substrate, and the n-type diffusion layers as a source and a drain, but this structure can be applied to a p-type channel MOS transistor. This structure can also be applied to a MOS transistor structure in which there is used a well having a substrate formed into a semiconductor substrate. Besides, this structure can also be applied to a MOS transistor including offset layers of low concentration, which are provided in the source diffusion layer and the drain diffusion layer.

In the MOS transistor according to the second embodiment of the present invention, the belt-like fins arranged in parallel to the gate length direction are formed in a stepwise manner in the gate width direction to thereby reduce the step height between the surface of the semiconductor substrate and a top portion of the fin. As a result, even in a case where the MOS transistor includes a high fin in order to enhance the driving performance per unit area, the MOS transistor can make the impurity concentration uniform in the channel region, the source diffusion layer, and the drain diffusion layer by using the ion implantation method.

With these structures, when a MOS transistor with high driving performance is incorporated into a VR or SWR, even if a MOS transistor whose gate width per unit area is increased by the use of the fins is used, there can be obtained a stable characteristic that variation in the characteristic due to a surface on which the channel is formed does not appear, and a lateral MOS transistor with high driving performance having a reduced on-resistance per unit area can be provided.

What is claimed is:

1. A semiconductor device, comprising:
a semiconductor substrate; and
a MOS transistor in which trenches are arranged in a channel region, a source diffusion layer, and a drain diffusion layer along a channel direction, disposed on the semiconductor substrate,
wherein the trenches have non-uniform depths and continuously include a first region which becomes gradually deeper in depth in a stepwise manner and a second region which becomes gradually shallower in depth in the stepwise manner in a direction perpendicular to the channel direction.

2. A semiconductor device, comprising;
a semiconductor substrate; and
a MOS transistor whose channel region has trenches arranged in parallel to a gate length direction and having a stepwise structure in a gate width direction, disposed on the semiconductor substrate.

3. A semiconductor device according to claim 2, wherein the stepwise structure protrudes downward from a surface of the semiconductor substrate.

4. A semiconductor device according to claim 2, wherein the stepwise structure protrudes upward from a surface of the semiconductor substrate.

5. A semiconductor device according to claim 3, wherein the stepwise structure comprises at least two steps in the channel region.

6. A semiconductor device according to claim 4, wherein the stepwise structure comprises at least two steps in the channel region.

7. A semiconductor device according to claim 2, wherein the MOS transistor comprises a source diffusion layer and a drain diffusion layer both having the stepwise structure.
